(19) United States
(12) Patent Application Publication
(10) Pub. No.: US 2026/0113907 A1
(43) Pub. Date: Apr. 23, 2026

(54) METHOD AND APPARATUS FOR CONTROLLING HEAT DISSIPATION DEVICE OF SERVER, STORAGE MEDIUM AND ELECTRONIC DEVICE

(71) Applicant: SUZHOU METABRAIN INTELLIGENT TECHNOLOGY CO., LTD., Suzhou, Jiangsu (CN)

(72) Inventors: Xiuqiang SUN, Suzhou, Jiangsu (CN); Feifei JI, Suzhou, Jiangsu (CN); Xiangfang WANG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 19/469,146

(22) PCT Filed: Sep. 29, 2024
(86) PCT No.: PCT/CN2024/122123

§ 371 Date: Sep. 25, 2025

(30) Foreign Application Priority Data
Feb. 28, 2024 (CN) 202410223197.9

(51) Int. Cl. H05K 7/20

(52) U.S. Cl. CPC H05K 7/20836

(57) ABSTRACT

A method and apparatus for controlling a heat dissipation device of a server, a non-transitory readable storage medium, and an electronic device. The method includes: detecting, in response to detecting the activation of a server host, a target slot deployment position of a target network interface card slot where a target network interface card device connected to the server host is inserted; selecting, from a heat dissipation device array, a first heat dissipation device in a target device deployment position corresponding to the target slot deployment position; and controlling the first heat dissipation device to operate on the basis of a target operating parameter.

### CROSS-REFERENCE TO RELATED APPLICATION

The present application is a National Stage Entry under 35 U.S.C. § 371 of PCT International Application No. PCT/CN2024/122123, filed on Sep. 20, 2024, which claims the priority to Chinese Patent Application No. 202410223197.9 filed to the China National Intellectual Property Administration on Feb. 28, 2024 and titled “Method and Apparatus for controlling Heat Dissipation Device of Server, Storage Medium and Electronic Device”, the entire contents of each of which are incorporated herein by reference for all purposes.

### TECHNICAL FIELD

Embodiments of the present disclosure relate to the field of computers, and particularly, to a method and apparatus for controlling a heat dissipation device of a server, a non-transitory readable storage medium, and an electronic device.

### BACKGROUND

In related art, network interface card devices are widely applied in servers of various architectures in data centers. Due to the high power consumption of the network interface card devices, if the heat dissipation of an entire server is not adjusted timely, the high temperature of an entire server system will cause parts inside the server or other core components to crash or shut down due to overheating. A crash or shutdown, once occurring, will cause fatal harm to service operations.

All of the traditional heat dissipation strategies monitor the temperature of the network interface card devices by means of a physical I2C (Inter-Integrated Circuit) link so as to adjust the heat dissipation strategy of the entire server.

### SUMMARY

According to some embodiments of the present disclosure, a method for controlling a heat dissipation device of a server is provided. The server comprises a server host and a server controller. The server host is deployed with a network interface card slot array and a heat dissipation device array. A slot deployment position of a network interface card slot in the network interface card slot array has a corresponding relationship with a device deployment position of a heat dissipation device in the heat dissipation device array. The network interface card slot is configured to be connected to a network interface card device. The heat dissipation device is configured to dissipate heat for the network interface card device connected to the corresponding network interface card slot. The method is applied to the server controller and comprises:
detecting, in response to detecting the activation of the server host, a target slot deployment position of a target network interface card slot where a target network interface card device connected to the server host is inserted;
selecting, from the heat dissipation device array, a first heat dissipation device in a target device deployment position corresponding to the target slot deployment position; and
controlling the first heat dissipation device to operate on the basis of a target operating parameter, wherein the target operating parameter is configured to enable the target network interface card device to reach a target operating state through dissipating heat, and the target operating state is a state that allows the target network interface card device to continue operating after the server host is activated.

In some embodiments, detecting the target slot deployment position of the target network interface card slot where the target network interface card device connected to the server host is inserted comprises: receiving the target slot deployment position sent by the server host, wherein the target slot deployment position is detected by the server host during a network interface card device enumeration stage in an activation process.

In some embodiments, receiving the target slot deployment position sent by the server host comprises: receiving the target slot deployment position sent by a basic input/output system deployed on the server host to the server controller after the operation of the network interface card device enumeration stage is completed.

In some embodiments, receiving the target slot deployment position sent by the server host comprises: detecting an activation progress of the basic input/output system deployed on the server host for activating the server host; sending, in response to the activation progress indicating that the basic input/output system has completed the operation of the network interface card device enumeration stage, a target request to the basic input/output system, wherein the target request is configured to request acquisition of a slot deployment position of a network interface card slot where a network interface card device connected to the server host is inserted; and receiving the target slot deployment position sent, in response to the target request, by the basic input/output system deployed on the server host to the server controller.

In some embodiments, selecting, from the heat dissipation device array, the first heat dissipation device in the target device deployment position corresponding to the target slot deployment position comprises: searching, from a slot deployment position and a device deployment position that have a corresponding relationship, for a device deployment position corresponding to the target slot deployment position as the target device deployment position; and determining a heat dissipation device in the heat dissipation device array that is located in the target device deployment position as the first heat dissipation device.

In some embodiments, selecting, from the heat dissipation device array, the first heat dissipation device in the target device deployment position corresponding to the target slot deployment position comprises: searching, from a slot deployment position and a device deployment position that have a corresponding relationship, for a first device deployment position corresponding to the target slot deployment position; acquiring a second device deployment position whose distance from the first device deployment position falls within a target distance range; determining the first device deployment position and the second device deployment position as the target device deployment positions; and determining heat dissipation devices in the heat dissipation device array that are located in the target device deployment positions as the first heat dissipation devices.

In some embodiments, controlling the first heat dissipation device to operate on the basis of the target operating parameter comprises: determining the target operating parameter on the basis of distribution information of the first heat dissipation device, wherein the distribution information is configured to indicate distribution of the first heat dissipation device on the server host; and controlling the first heat dissipation device to operate on the basis of the target operating parameter.

In some embodiments, determining the target operating parameter on the basis of distribution information of the first heat dissipation device comprises: in response to the distribution information being configured to indicate that the first heat dissipation device is a heat dissipation device in the heat dissipation device array whose device deployment position has a corresponding relationship with the target slot deployment position, acquiring a maximum operating parameter of the first heat dissipation device; and determining the maximum operating parameter as the target operating parameter.

In some embodiments, determining the target operating parameter on the basis of distribution information of the first heat dissipation device comprises: in response to the distribution information being configured to indicate that a target slot deployment position of the first heat dissipation device comprises a first device deployment position and a second device deployment position, allocating an operating parameter to a heat dissipation device of the first heat dissipation devices on the basis of the maximum operating parameter of the first heat dissipation device and a distance between the heat dissipation devices of the first heat dissipation devices, wherein the first device deployment position is a device deployment position corresponding to the target slot deployment position searched from the slot deployment position and the device deployment position that have a corresponding relationship, and the second device deployment position is a device deployment position whose distance from the first device deployment position falls within a target distance range; and determining the operating parameter having the corresponding relationship with the heat dissipation devices as the target operating parameter.

In some embodiments, allocating the operating parameter to the heat dissipation device of the first heat dissipation devices on the basis of the maximum operating parameter of the first heat dissipation device and the distance between the heat dissipation devices of the first heat dissipation devices comprises: determining, on the basis of the maximum operating parameter of the first heat dissipation device, a first operating parameter for a heat dissipation device in the first device deployment position, wherein the first operating parameter is less than or equal to the maximum operating parameter; and determining, on the basis of the first operating parameter and a distance between the second device deployment position and the first device deployment position, a second operating parameter for a heat dissipation device in the second device deployment position, wherein the distance is inversely proportional to the second operating parameter.

In some embodiments, allocating the operating parameter to the heat dissipation device of the first heat dissipation devices on the basis of the maximum operating parameter of the first heat dissipation device and the distance between the heat dissipation devices of the first heat dissipation devices comprises: allocating a first operating parameter to a heat dissipation device in the first device deployment position and allocating a second operating parameter to a heat dissipation device in the second device deployment position, wherein the first operating parameter is less than or equal to the maximum operating parameter, and the second operating parameter is less than or equal to the first operating parameter.

In some embodiments, before detecting the target slot deployment position of the target network interface card slot where the target network interface card device connected to the server host is inserted, the method further comprises: in response to detecting that the server host is powered on, detecting current power-on information of the server host, wherein the current power-on information is configured to indicate a power-on condition under which the server host is powered on this time; determining, on the basis of the current power-on information, in-place information of a network interface card slot in the network interface card slot array, wherein the in-place information is configured to indicate an in-place condition of a network interface card device on the corresponding network interface card slot; and screening out, on the basis of the in-place information, a second heat dissipation device from the heat dissipation device array and controlling the second heat dissipation device to operate on the basis of a reference operating parameter, wherein the reference operating parameter is configured to enable the network interface card slot array to reach a reference operating state through dissipating heat, and the reference operating state is an operating state of the network interface card slot array under which the server host is allowed to be activated.

In some embodiments, determining, on the basis of the current power-on information, in-place information of the network interface card slot in the network interface card slot array comprises: in response to the current power-on information being configured to indicate that the server host is powered on for the first time, determining that the in-place information is configured to indicate that there is a network interface card slot in the network interface card slot array that is connected to the network interface card device. Screening out, on the basis of the in-place information, the second heat dissipation device from the heat dissipation device array and controlling the second heat dissipation device to operate on the basis of the reference operating parameter comprises: determining all heat dissipation devices in the heat dissipation device array as the second heat dissipation devices; allocating, on the basis of the device deployment positions of the heat dissipation devices in the heat dissipation device array, operating parameters to the second heat dissipation devices to obtain the reference operating parameter; and controlling the second heat dissipation devices to operate on the basis of the reference operating parameter.

In some embodiments, determining, on the basis of the current power-on information, in-place information of the network interface card slot in the network interface card slot array comprises: in response to the current power-on information being configured to indicate that the server host has never been activated, determining that the in-place information is configured to indicate that a default network interface card slot in the network interface card slot array is connected to a network interface card device. Screening out, on the basis of the in-place information, the second heat dissipation device from the heat dissipation device array comprises: determining, as the second heat dissipation device, a heat dissipation device in the heat dissipation device array whose device deployment position corresponds to a slot deployment position of the default network interface card slot.

In some embodiments, determining, on the basis of the current power-on information, in-place information of the network interface card slot in the network interface card slot array comprises: in response to the current power-on information being configured to indicate that the server host has been activated before, determining the in-place information of the network interface card slot in the network interface card slot array on the basis of a target slot deployment position of a target network interface card slot where a target network interface card device connected to the server host is inserted, as detected during historical activation of the server host. Screening out, on the basis of the in-place information, the second heat dissipation device from the heat dissipation device array comprises: determining, as the second heat dissipation device, a heat dissipation device in the heat dissipation device array that corresponds to the slot deployment position of the network interface card slot of the network interface card device connected to the server host, as detected during historical activation of the server host.

In some embodiments, determining, on the basis of the current power-on information, in-place information of the network interface card slot in the network interface card slot array comprises: in response to the current power-on information being configured to indicate that the server host is not powered on for the first time, determining that the in-place information is configured to indicate that the network interface card device connected to the server host at the time of the server host's last powered off is in place. Screening out, on the basis of the in-place information, the second heat dissipation device from the heat dissipation device array comprises: acquiring a candidate slot deployment position of the network interface card slot where the network interface card device connected to the server host is located at the time of the server host's last powered off; searching, from the slot deployment position and the device deployment position that have a corresponding relationship, for a candidate device deployment position corresponding to the candidate slot deployment position; and determining a heat dissipation device in the candidate device deployment position as the second heat dissipation device.

According to some embodiments of the present disclosure, a apparatus for controlling a heat dissipation device of a server is provided. The server comprises a server host and a server controller. The server host is deployed with a network interface card slot array and a heat dissipation device array. A slot deployment position of a network interface card slot in the network interface card slot array has a corresponding relationship with a device deployment position of a heat dissipation device in the heat dissipation device array. The network interface card slot is configured to be connected to a network interface card device. The heat dissipation device is configured to dissipate heat of the network interface card device connected to the corresponding network interface card slot. The apparatus is applied to the server controller and comprises:
a first detection module, configured to detect, in response to detecting the activation of the server host, a target slot deployment position of a target network interface card slot where a target network interface card device connected to the server host is inserted;
a first screening module, configured to select, from a heat dissipation device array, a first heat dissipation device in a target device deployment position corresponding to the target slot deployment position; and
a control module, configured to control the first heat dissipation device to operate on the basis of a target operating parameter, wherein the target operating parameter is configured to enable the target network interface card device to reach a target operating state through dissipating heat, and the target operating state is a state that allows the target network interface card device to continue operating after the server host is activated.

According to some embodiments of the present disclosure, further provided is a non-transitory computer readable storage medium, storing a computer program therein, wherein the computer program is configured to, when executed, perform the steps in any one of the method embodiments above.

According to embodiments of the present disclosure, further provided is an electronic device, comprising a memory and a processor, wherein a computer program is stored in the memory, and the processor is configured to execute the computer program to perform the steps in any one of the method embodiments above.

According to embodiments of the present disclosure, further provided is a computer program product comprising a computer program, wherein the computer program, when executed by a processor, implements the steps in any one of the method embodiments above.

### BRIEF DESCRIPTION OF THE DRAWINGS

FIG. 1 is a hardware structural block diagram of a server device for a method for controlling a heat dissipation device of a server according to embodiments of the present disclosure;

FIG. 2 is a flowchart of a method for controlling a heat dissipation device of a server according to embodiments of the present disclosure;

FIG. 3 is a schematic diagram of an entire server according to embodiments of the present disclosure;

FIG. 4 is a schematic diagram of a server motherboard according to embodiments of the present disclosure;

FIG. 5 is a schematic diagram of a rotational speed of a fan according to embodiments of the present disclosure;

FIG. 6 is a flowchart of a working process of a server controller according to embodiments of the present disclosure;

FIG. 7 is a swim lane diagram of a control process for a heat dissipation device of a server according to embodiments of the present disclosure;

FIG. 8 is a structural block diagram of a control apparatus for a heat dissipation device of a server according to embodiments of the present disclosure; and

FIG. 9 is a structural block diagram of an electronic device according to embodiments of the present disclosure.

### DETAILED DESCRIPTION OF THE EMBODIMENTS

Embodiments of the present disclosure are described in detail below with reference to the drawings and in combination with the embodiments.

It is to be noted that the terms “first”, “second”, and the like in the description, claims, and drawings above of the present application are used to distinguish similar objects, and are not necessarily used to describe a specific order or sequence.

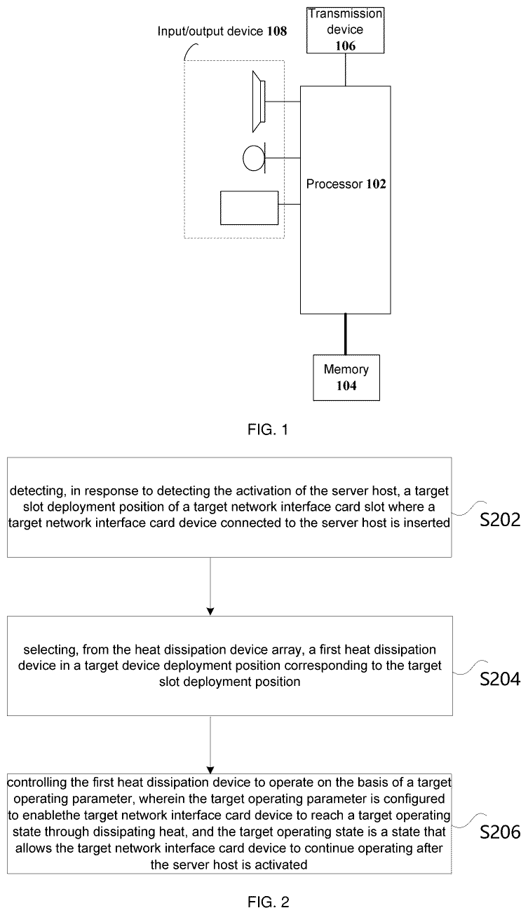

The method embodiments provided in the embodiments of the present disclosure may be executed in a server device or a similar computing apparatus. In an example that the method embodiment operates on a server device, FIG. 1 is a hardware structural block diagram of a server device for a method for controlling a heat dissipation device of a server according to embodiments of the present disclosure. As shown in FIG. 1, the server device may comprise one or more (only one shown in FIG. 1) processors 102 (the processor 102 may include but is not limited to a processing apparatus such as a Microcontroller Unit (MCU) or a Field Programmable Gate Array (FPGA)) and a memory 104 configured to store data, wherein the server device hereinabove may further comprise a transmission device 106 for a communication functionality and an input/output device 108. A person of ordinary skill in the art will appreciate that the structure shown in FIG. 1 is merely illustrative and is not intended to limit the structure of the server device hereinabove. For example, the server device may further comprise more or fewer components than those shown in FIG. 1 or have a configuration different from that shown in FIG. 1.

The memory 104 may be configured to store a computer program, for example, a software program of an application software and a module, such as the computer program corresponding to the method for controlling the heat dissipation device of the server in the embodiments of the present disclosure. The processor 102 executes various functional applications and data processing by executing the computer program stored in the memory 104, thereby implementing the method hereinabove. The memory 104 may comprise a high-speed random-access memory, or may comprise a non-transitory memory, such as one or more magnetic storage apparatuses, a flash memory, or other non-transitory solid-state memories. In some examples, the memory 104 may comprise memories remotely disposed relative to the processor 102, wherein these remote memories may be connected to the server device over a network. Examples of the network hereinabove include, but are not limited to, the Internet, an intranet, a local area network, a mobile communication network and a combination thereof.

The transmission device 106 is configured to receive or send data over a network. Examples of the network hereinabove may comprise a wireless network provided by a communication provider of the server device. In an example, the transmission device 106 comprises a network interface controller (NIC), which may be connected to other network devices via a base station, so as to communicate with the Internet. In an example, the transmission device 106 may be a radio frequency (RF) module, which is configured to wirelessly communicate with the Internet.

According to embodiments of the present disclosure, a method for controlling a heat dissipation device of a server is provided. The server comprises a server host and a server controller. The server host is deployed with a network interface card slot array and a heat dissipation device array. A slot deployment position of a network interface card slot in the network interface card slot array has a corresponding relationship with a device deployment position of a heat dissipation device in the heat dissipation device array. The network interface card slot is configured to be connected to a network interface card device. The heat dissipation device is configured to dissipate heat of the network interface card device connected to the corresponding network interface card slot. The method is applied to the server controller. FIG. 2 is a flowchart of a method for controlling a heat dissipation device of a server according to embodiments of the present disclosure. As shown in FIG. 2, the workflow comprises the following steps:
at step S202, detecting, in response to detecting the activation of the server host, a target slot deployment position of a target network interface card slot where a target network interface card device connected to the server host is inserted;
at step S204, selecting, from the heat dissipation device array, a first heat dissipation device in a target device deployment position corresponding to the target slot deployment position; and at step S206, controlling the first heat dissipation device to operate on the basis of a target operating parameter, wherein the target operating parameter is configured to enable the target network interface card device to reach a target operating state through dissipating heat, and the target operating state is a state that allows the target network interface card device to continue operating after the server host is activated.

With the steps hereinabove, the server controller detects a target slot deployment position of a target network interface card slot where a target network interface card device connected to the server host is inserted, and a first heat dissipation device in a target device deployment position corresponding to the target slot deployment position is screened from a heat dissipation device array, such that the first heat dissipation device can be adjusted in real time to operate on the basis of a target operating parameter even in a case where the heat dissipation device in the heat dissipation device array does not have a physical I2C link to monitor the temperature of the network interface card device to adjust the heat dissipation strategy of the entire server. Therefore, it's possible to solve the problem of low control efficiency of the heat dissipation device of the server, achieving the effect of improving the control efficiency of the heat dissipation device of the server.

In some embodiments of the present disclosure, the method for controlling a heat dissipation device of a server proposed in the present disclosure is applied to the server controller deployed on the server, wherein the server controller hereinabove may include but is not limited to a BMC (Baseboard Management Controller) or other devices having a server management functionality.

In some embodiments of the present disclosure, the server host hereinabove is deployed with a network interface card slot array comprising a plurality of network interface card slots, wherein the network interface card slots hereinabove are configured to be connected to network interface card devices, and it's possible to, but not limited so, arrange the network interface card slots hereinabove by multiple manners to obtain the network interface card slot array, for example, parallel arrangement, vertical arrangement, or hybrid arrangement including both parallel arrangement and vertical arrangement.

In some embodiments of the present disclosure, the network interface card device hereinabove may include, but is not limited to, a basic function network interface card, an SNIC (Smart Network Interface Card), a DPU (Data Processing Unit) smart network interface card, and other devices that have a computing capability, are capable of undertaking data processing functionalities related to networks, security, and storage that are unsuitable for a CPU (Central Processing Unit), reduce the consumption of the CPU, enable the server to more efficiently run critical applications and an operating system, and implement functionalities of optimizing overall effectiveness of service data processing.

It should be noted that in the related art, a DPU is an entity that delivers virtualization functionalities, which is formed by a specialized processor designed to provide data center infrastructure virtualization services such as networking, storage, security, and management with respect to data processing, and a computing architecture formed by a CPU based on ARM (Advanced RISC Machine)/X86 or other architectures and a specialized hardware acceleration engine such as an ASIC (Application Specific Integrated Circuit)/NP (Network Processor)/FPGA (Field Programmable Gate Array). The DPU is applicable to servers of various architectures in a data center, including, but not limited to, the X86 architecture and the ARM architecture, etc. Since the DPU has high power consumption, if the heat dissipation control of the entire server is not adjusted timely, the high temperature of the entire server system will cause internal parts or other core components to become unusable due to overheating, resulting in crash or shutdown. Once the crash or shutdown occurs unknowingly, they will cause fatal harm to service operations. Therefore, the server of any architecture needs to establish a reasonable heat dissipation strategy.

In some embodiments of the present disclosure, the server host hereinabove is further deployed with a heat dissipation device array comprising a plurality of heat dissipation devices, wherein the heat dissipation devices hereinabove are devices configured to dissipate heat of network interface card devices connected to corresponding network interface card slots, such as fan devices, heat sinks, heat dissipation pipes, heat dissipation channels, etc. It's possible to, but not limited so, arrange the heat dissipation devices by multiple manners to obtain the heat dissipation device array, for example, parallel arrangement, vertical arrangement, and hybrid arrangement including both parallel arrangement and vertical arrangement.

In some embodiments of the present disclosure, it's possible to, but not limited so, connect network interface card devices to one or more network interface card slots in the network interface card slot array, and control one or more corresponding heat dissipation devices to dissipate heat for the network interface card devices.

In the technical solution provided at step S202 hereinabove, the target network interface card slot connected to the network interface card device may be determined by, but not limited so, detecting the connection status of the network interface card slot on the server host, thereby obtaining the target slot deployment position of the target network interface card slot.

In some embodiments of the present disclosure, the connection status of the network interface card slot on the server host may be detected by means of, but not limited so, a device having hardware detection and identification functionalities, such as a BIOS (Basic Input/Output System), a UEFI (Unified Extensible Firmware Interface), etc.

In some embodiments, the target slot deployment position of the target network interface card slot where the target network interface card device connected to the server host is inserted may be detected by, but not limited so: receiving the target slot deployment position sent by the server host, wherein the target slot deployment position is detected by the server host during a network interface card device enumeration stage of the activation process.

In some embodiments of the present disclosure, during the activation of the server host, the target network interface card slot connected to the target network interface card device may be detected by, but not limited so, the network interface card device enumeration stage, wherein the network interface card device enumeration stage hereinabove may be, but is not limited to be, configured to allocate a bus number and allocate a BAR (Base Address Register) space, wherein the allocated bus number is configured to access a configuration space, and the BAR space is configured to perform data interaction with a PCIe (Peripheral Component Interconnect express) device.

In some embodiments of the present disclosure, in a case where the server host is activated, the server host may be, but is not limited to be, configured to send, to the server controller, the target slot deployment position of the target network interface card slot connected to the target network interface card device. The server host may, but is not limited to, immediately send the target slot deployment position to the server controller upon the completion of the activation of the server host, or may send the target slot deployment position to the server controller in response to a request from the server controller in a case where the server host has been activated. In some embodiments, the server host may also trigger, in response to other set triggering conditions, the operation of sending the target slot deployment position to the server controller.

In some embodiments of the present disclosure, the server host may transfer the target slot deployment position of the target network interface card slot to the server controller by means of, but not limited so, an IPMI (Intelligent Platform Management Interface) command or other transmission protocols supportable by the server controller.

In some embodiments, the target slot deployment position sent by the server host may be received by, but not limited so: receiving the target slot deployment position sent by the basic input/output system deployed on the server host to the server controller after completing the operation of the network interface card device enumeration stage.

In some embodiments of the present disclosure, during the activation of the server host, the basic input/output system deployed on the server host may be, but is not limited to be, configured to detect the target network interface card slot connected to the target network interface card device via the network interface card device enumeration stage, and upon the completion of the network interface card device enumeration stage, actively send the target slot deployment position to the server controller.

In some embodiments of the present disclosure, in a case where the basic input/output system completes the network interface card device enumeration stage, the basic input/output system may transfer the target slot deployment position of the target network interface card slot to the server controller by means of, but not limited to, an IPMI command or other transmission protocols supportable by the server controller.

In some embodiments, the target slot deployment position sent by the server host may be received by, but not limited so: detecting an activation progress of the basic input/output system deployed on the server host for activating the server host; in response to the activation progress being configured to indicate that the basic input/output system has completed the operation of the network interface card device enumeration stage, sending a target request to the basic input/output system, wherein the target request is configured to request acquisition of the slot deployment position of the network interface card slot where the network interface card device connected to the server host is inserted; and receiving the target slot deployment position sent, in response to the target request, by the basic input/output system deployed on the server host to the server controller.

In some embodiments of the present disclosure, the server host may, but is not limited to, perform an activation operation by means of booting of the basic input/output system. During the basic input/output system boots the activation of the server host, the slot deployment position of the network interface card slot where the network interface card device connected to the server host is inserted may be obtained by means of, but not limited so, the network interface card device enumeration stage. In a case where the basic input/output system has completed the operation of the network interface card device enumeration stage, the server controller sends a target request to the basic input/output system to request acquiring the slot deployment position of the network interface card slot where the network interface card device connected to the server host is inserted, and receives the target slot deployment position sent by the basic input/output system deployed on the server host in response to the target request.

In some embodiments of the present disclosure, the basic input/output system and the server controller may interact with each other by means of, but not limited so, an IPMI command or other transmission protocols supportable by the server controller.

In some embodiments, before the detection of the target slot deployment position of the target network interface card slot where the target network interface card device connected to the server host is inserted, the operation of the heat dissipation device may be controlled by, but not limited so: in response to detecting that the server host is powered on, detecting current power-on information of the server host, wherein the current power-on information is configured to indicate a power-on condition under which the server host is powered on this time; determining, on the basis of the current power-on information, in-place information of the network interface card slot in the network interface card slot array, wherein the in-place information is configured to indicate an in-place condition of the network interface card device on the corresponding network interface card slot; and screening out, on the basis of the in-place information, a second heat dissipation device from the heat dissipation device array and controlling the second heat dissipation device to operate on the basis of a reference operating parameter, wherein the reference operating parameter is configured to enable the network interface card slot array to reach a reference operating state through dissipating heat, and the reference operating state is an operating state of the network interface card slot array under which the server host is allowed to be activated.

In some embodiments of the present disclosure, it is possible, but not limited so, to power on the server host without activating the server, such that the server host is in a powered-on but un-activated state, and it's detected, as the current power-on information of the server host, whether the server host is powered on for the first time, that is, whether the server host has been activated before, wherein the current power-on information of the server host may include, but is not limited to, the server being powered on for the first time, that is, the server host having not been activated before. Alternatively, the server is not powered on for the first time, that is, the server host has been activated before.

In some embodiments of the present disclosure, in a case where the server host is activated, the server host may be, but is not limited to be, configured to detect the target slot deployment position of the target network interface card slot where the target network interface card device connected to the server host is inserted, and therefore may, but not limited so, determine the in-place information of the network interface card slot in the network interface card slot array on the basis of the current power-on information of the server host, for example, it's determined that the in-place information of the network interface card slot in the network interface card slot array is unknown being configured to the current power-on information of the server host being configured to indicate that the server host has never been activated. Alternatively, in response to the current power-on information of the server host being configured to indicate that the server host has been activated before, the in-place information of the network interface card slot in the network interface card slot array is determined on the basis of the target slot deployment position of the target network interface card slot where the target network interface card device connected to the server host is inserted, which is detected in a historical server host activation process.

In some embodiments, in a case where the current power-on information of the server host indicates that the server host has never been activated, since the in-place information of the network interface card slot in the network interface card slot array is unknown, in order to protect the server host from overheating caused by the network interface card device during the current activation process, it is possible to, but not limited so, set a default in-place network interface card device and control the heat dissipation device corresponding to the slot deployment position of the network interface card slot of the default in-place network interface card device to perform heat dissipation operation, thereby dissipating heat for the network interface card devices connected to all the network interface card slots, enabling the server host not to experience overheating during the normal activation process regardless of which network interface card slot the current network interface card device is deployed in.

In some embodiments of the present disclosure, it's possible to, but not limited so, determine the heat dissipation device corresponding to the in-place network interface card device in the network interface card slot as a second heat dissipation device. For example, in response to the current power-on information of the server host indicating that the server host has been activated before, the heat dissipation device in the heat dissipation device array corresponding to the target slot deployment position of the target network interface card slot where the target network interface card device connected to the server host is inserted, as detected during the historical server host activation process, is determined as the second heat dissipation device, on the basis of the in-place information, wherein the in-place information of the network interface card slot in the network interface card slot array is determined on the basis of the target slot deployment position of the target network interface card slot where the target network interface card device connected to the server host is inserted, as detected during the historical server host activation process.

In some embodiments, in a case where the current power-on information of the server host indicates that the server host has never been activated, since the in-place information of the network interface card slot in the network interface card slot array is unknown, in order to protect the server host from overheating due to the network interface card device during the current activation process, the in-place network interface card devices is configured to comprise all network interface card devices except the first and last network interface card devices, and the second heat dissipation device comprises the heat dissipation device corresponding to the in-place network interface card device. In some embodiments, in a case where the current power-on information of the server host indicates that the server host has never been activated, since the in-place information of the network interface card slot in the network interface card slot array is unknown, in order to protect the server host from overheating due to the network interface card device during the current activation process, all the network interface card devices are configured to be in place, and the second heat dissipation devices comprise all heat dissipation devices.

It should be noted that in a case where the current power-on information of the server host indicates that the server host has never been activated, since the in-place information of the network interface card slot in the network interface card slot array is unknown, it's possible to, but not limited so, configure the default in-place network interface card device adaptively on the basis of the network interface card slot array deployed on the server host, so as to ensure that during the current activation process of the server host, the server host can be activated normally regardless of which network interface card slot the network interface card device is deployed in, that is, no overheating problem will occur.

In some embodiments of the present disclosure, the reference operating parameter is configured to dissipate heat of the network interface card slot array to a state that allows the server host to activate, and the reference operating parameter of the second heat dissipation device may be, but not limited to be, determined on the basis of the temperature condition for normal activation of the server host and the heat generated during the activation process of the server host.

In some embodiments, the reference operating parameter of the second heat dissipation device hereinabove may be, include but not limited to be, calculated by various means on the basis of the temperature condition for the normal activation of the server host and the heat generated during the activation process of the server host, for example, a deep learning model may be trained to calculate the reference operating parameter of the second heat dissipation device hereinabove, or the reference operating parameter of the second heat dissipation device hereinabove may be calculated by an algorithm, etc.

In some embodiments of the present disclosure, the operating parameter of the heat dissipation device may be, but not limited to be, determined on the basis of parameters such as a rotational speed and air volume of the heat dissipation device, etc.

In some embodiments, the in-place information of network interface card slot in the network interface card slot array may be determined on the basis of the current power-on information by, but not limited so: in response to the current power-on information being configured to indicate that the server host is powered on for the first time, determining that the in-place information is configured to indicate there is a network interface card slot in the network interface card slot array that is connected to network interface card device. The second heat dissipation device may be screened out from the heat dissipation device array on the basis of the in-place information and the second heat dissipation device is controlled to operate on the basis of the reference operating parameter by, but not limited so: determining all heat dissipation devices in the heat dissipation device array as the second heat dissipation devices; allocating operating parameters to the second heat dissipation devices on the basis of device deployment positions of the heat dissipation devices in the heat dissipation device array to obtain the reference operating parameter; and controlling the second heat dissipation devices to operate on the basis of the reference operating parameter.

In some embodiments of the present disclosure, in a case where the current power-on information indicates that the server host is powered on for the first time, it's determined that there is a network interface card slot in the network interface card slot array which is connected to the network interface card device, and all heat dissipation devices in the heat dissipation device array are determined as the second heat dissipation devices. Operating parameters are allocated to the second heat dissipation devices on the basis of the device deployment positions of the heat dissipation devices in the heat dissipation device array to obtain the reference operating parameter, and the second heat dissipation devices are controlled to operate on the basis of the reference operating parameter.

In some embodiments of the present disclosure, in an example where the heat dissipation device array is formed by the heat dissipation devices in parallel arrangement and comprises a heat dissipation device 1, a heat dissipation device 2, a heat dissipation device 3, a heat dissipation device 4 and a heat dissipation device 5, all the heat dissipation devices in the heat dissipation device array are determined as the second heat dissipation devices, and operating parameters may be allocated to the second heat dissipation devices on the basis of device deployment positions of the heat dissipation devices to obtain the reference operating parameters by, but not limited so:
allocating a larger operating parameter of 80% to the dissipation device 2 and the dissipation device 4, while allocating a smaller operating parameter of 30% to the heat dissipation device 1, the heat dissipation device 3 and the heat dissipation device 5 since the heat dissipation device 2 and the heat dissipation device 4 are capable of dissipating heat for the corresponding network interface card device 1, network interface card device 2, network interface card device 3, network interface card device 4 and network interface card device 5; or
allocating an operating parameter of 75% to the heat dissipation device 2, the heat dissipation device 3 and the heat dissipation device 4, and allocating an operating parameter of 30% to the heat dissipation device 1 and the heat dissipation device 5, since the heat dissipation device 2, the heat dissipation device 3 and the heat dissipation device 4 can also be implemented to dissipate heat for the network interface card device 1, the network interface card device 2, the network interface card device 3, the network interface card device 4 and the network interface card device 5; or
allocating an operating parameter of 75% to the heat dissipation device 3, the heat dissipation device 4, and the heat dissipation device 5, and allocating an operating parameter of 30% to the heat dissipation device 1 and the heat dissipation device 2; or
allocating an operating parameter of 30% to each of the heat dissipation device 1, the heat dissipation device 2, the heat dissipation device 3, the heat dissipation device 4, and the heat dissipation device 5.

Due to the differences in the server hosts where the network interface card slot array and the heat dissipation device are deployed, there are also differences in the network interface card slot array and the heat dissipation device array deployed on the server hosts. Therefore, the operating parameter of the second heat dissipation device may be adaptively adjusted on the basis of, but not limited so, the network interface card slot array and heat dissipation device array deployed on the server host, such that the heat dissipation device operating on the basis of the operating parameter can ensure the normal activation of the server host.

In some embodiments, the in-place information of the network interface card slot in the network interface card slot array may be determined on the basis of the current power-on information by, but not limited so: in response to the current power-on information being configured to indicate that the server host is not powered on for the first time, determining that the in-place information is configured to indicate that the network interface card device connected to the server host at the time of the server host's last powered off is in place. The second heat dissipation device may be screened out from the heat dissipation device array on the basis of the in-place information by, but not limited so: acquiring a candidate slot deployment position of the network interface card slot where the network interface card device connected to the server host is located at the time of the server host's last powered off; searching, from the slot deployment position and the device deployment position that have a corresponding relationship, for a candidate device deployment position corresponding to the candidate slot deployment position; and determining a heat dissipation device in the candidate device deployment position as the second heat dissipation device.

In some embodiments of the present disclosure, in a case where the current power-on information indicates that the server host is not powered on for the first time, it is possible to determine that the network interface card device connected to the server host at the time of the server host's last powered off is in place, and acquire a candidate slot deployment position of the network interface card slot where the network interface card device connected to the server host is located at the time of the server host's last powered off. A candidate device deployment position corresponding to the candidate slot deployment position is searched from the slot deployment position and the device deployment position that have a corresponding relationship, and the heat dissipation device in the candidate device deployment position is determined as the second heat dissipation device.

In some embodiments of the present disclosure, in a case where the current power-on information indicates that the server host is not powered on for the first time, it's possible to, but is not limited to, allocate a corresponding reference operating parameter to the second heat dissipation device and control the second heat dissipation device to operate on the basis of the reference operating parameter, wherein the second heat dissipation device may include, but is not limited to, one or more heat dissipation devices. It is possible to, but not limited so, adaptively adjust the reference operating parameter of the second heat dissipation device to ensure that the heat dissipation device operating on the basis of the operating parameter can ensure the normal activation of the server host.

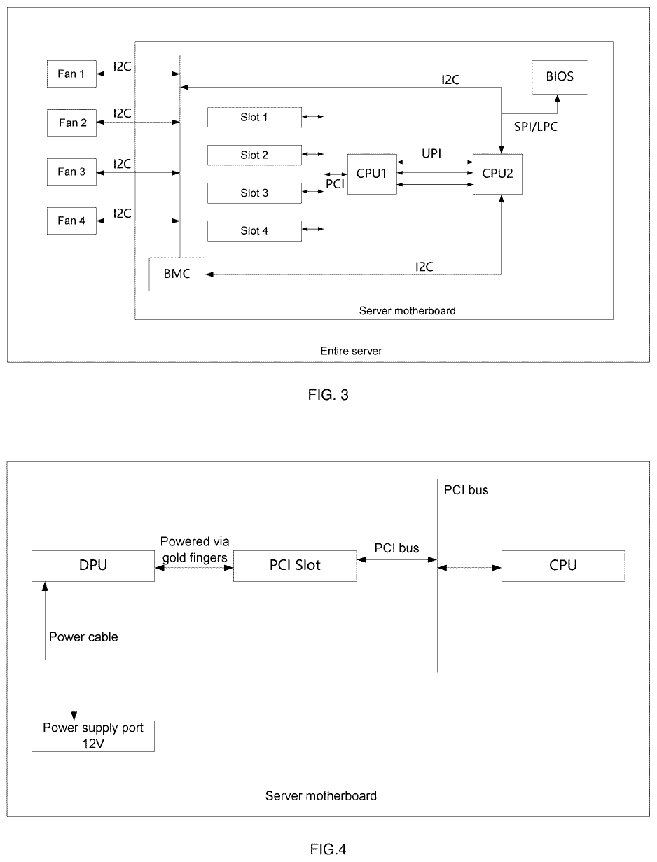

In some embodiments, an example of an entire server is provided. FIG. 3 is a schematic diagram of an entire server according to embodiments of the present disclosure. As shown in FIG. 3, the entire server hereinabove comprises a server motherboard and a heat dissipation device array, wherein the server controller is a BMC deployed on the server motherboard, and the heat dissipation device array comprises a fan 1, a fan 2, a fan 3 and a fan 4. A network interface card slot array comprises a slot 1, a slot 2, a slot 3 and a slot 4. The server motherboard is further deployed with a CPU1 and a CPU2, wherein the CPU1 and the CPU2 communicate with each other via a UPI (Ultra Path Interconnect) protocol. The slots in the network interface card slot array may, but are not limited to, communicate with the CPUs via PCI (Peripheral Component Interconnect). The fans in the heat dissipation device array communicate with the BMC and the CPUs via I2C. In a case where the server host is powered on, the BMC may operate by, but not limited so:
determining, by the BMC, whether the server host is powered on for the first time; and
in a case where the server host is powered on for the first time, determining that there is a network interface card slot in the network interface card slot array which is connected to a network interface card device; the BMC may, but is not limited to, screen out the second heat dissipation device comprising the fan 1, the fan 2, the fan 3, and the fan 4, and allocate a reference operating parameter thereto, including allocating a rotational speed of 73% to the fan 3 and the fan 4 and a rotational speed of 30% to the fan 1 and the fan 2; and
in a case where the server host is not powered on for the first time, acquiring a candidate slot deployment position of the network interface card slot where the network interface card device connected during the last shutdown is located; in an example where the candidate slot deployment position is the slot 2, it is possible to, but not limited so, determine the second heat dissipation device corresponding to the slot 2 as the fan 2 and allocate an operating parameter comprising a rotational speed of 30% to the fan 2.

In a case where the server host is not powered on for the first time, the candidate slot deployment position of the network interface card slot where the network interface card device connected during the last shutdown is located may be, but is not limited to be, detected by the BIOS during a network interface card device enumeration stage and transmitted to the BMC via an SPI (Serial Peripheral Interface) or a LPC (Low Pin Count) protocol.

In some embodiments, an example of a server motherboard is provided. FIG. 4 is a schematic diagram of a server motherboard according to embodiments of the present disclosure. As shown in FIG. 4, in an example where the network interface card device is a DPU, in the server, the DPU is connected to a PCI slot, and powered via gold fingers, wherein the PCI slot interacts with the CPU via a PCI bus.

In the technical solution provided at step S204 hereinabove, it is possible to, but not limited so, screen out, from the heat dissipation device array, a first heat dissipation device in a target device deployment position corresponding to a target slot deployment position on the basis of a corresponding relationship between the slot deployment position of the network interface card slot in the network interface card slot array and the device deployment position of the heat dissipation device in the heat dissipation device array.

In some embodiments of the present disclosure, the corresponding relationship between the slot deployment position of the network interface card slot in the network interface card slot array and the device deployment position of the heat dissipation device in the heat dissipation device array may be, but is not limited to be, a one-to-one corresponding relationship, or may be a many-to-many corresponding relationship. Therefore, the first heat dissipation devices may be, but are not limited to be, the same number of heat dissipation devices as the target slot deployment positions, or may be a different number of heat dissipation devices.

In some embodiments, the first heat dissipation device in the target device deployment position corresponding to the target slot deployment position may be screened out from the heat dissipation device array by, but not limited so: searching, from the slot deployment position and the device deployment position that have a corresponding relationship, for the device deployment position corresponding to the target slot deployment position as the target device deployment position; and determining the heat dissipation device in the heat dissipation device array which is located in the target device deployment position as the first heat dissipation device.

In some embodiments of the present disclosure, it is possible to, but not limited so, search, from the slot deployment position and the device deployment position that have a corresponding relationship, for the device deployment position corresponding to the target slot deployment position as the target device deployment position, and determine the heat dissipation device in the heat dissipation device array which is located in the target device deployment position as the first heat dissipation device.

In some embodiments, the first heat dissipation device in the target device deployment position corresponding to the target slot deployment position may be screened out from the heat dissipation device array by, but not limited so: searching, from the slot deployment position and the device deployment position that have a corresponding relationship, for the first device deployment position corresponding to the target slot deployment position; acquiring a second device deployment position whose distance from the first device deployment position falls within a target distance range; determining the first device deployment position and the second device deployment positions as the target device deployment positions; and determining the heat dissipation devices in the heat dissipation device array which are located in the target device deployment positions as the first heat dissipation devices.

In some embodiments of the present disclosure, it's possible to, but not limited so, determine the target distance range hereinabove on the basis of the network interface card slot array, for example, in a case where the network interface card slot array is in parallel arrangement, a certain horizontal distance is determined as the target distance range hereinabove; in a case where the network interface card slot array is in vertical arrangement, a certain vertical distance is determined as the target distance range hereinabove; and in a case where the network interface card slot array is in hybrid arrangement including both parallel arrangement and vertical arrangement, a distance within a certain radius is determined as the target distance range hereinabove. The distance hereinabove may be, but is not limited to be, determined on the basis of the number of network interface card slots included in the network interface card slot array, for example, ½, ¼, etc. of the number of network interface card slots.

In some embodiments of the present disclosure, the target device deployment position comprises a first device deployment position corresponding to the target slot deployment position and a second device deployment position whose distance from the first device deployment position falls within the target distance range, and it's possible to, but not limited so, determine the heat dissipation device in the heat dissipation device array which is located in the target device deployment position as the first heat dissipation device.

In the technical solution provided at step S206 hereinabove, it is possible to, but not limited so, control the first heat dissipation device to operate on the basis of the target operating parameter, to enable the target network interface card device to continue operating after the server host is activated.

In some embodiments of the present disclosure, the operating parameter of the heat dissipation device may be, but not limited to be, determined on the basis of parameters such as a rotational speed and air volume of the heat dissipation device, etc.

In some embodiments, the first heat dissipation device may be controlled to operate on the basis of the target operating parameter by, but not limited so: determining the target operating parameter on the basis of distribution information of the first heat dissipation devices, wherein the distribution information is configured to indicate a distribution status of the first heat dissipation devices on the server host; and controlling the first heat dissipation device to operate on the basis of the target operating parameter.

In some embodiments of the present disclosure, the first heat dissipation device may be, but is not limited to, one or more heat dissipation devices on the server host, and it is possible to, but not limited so, determine the target operating parameter of the first heat dissipation device on the basis of the distribution status of the first heat dissipation devices in the heat dissipation device array. For example, in a case where the first heat dissipation device is a heat dissipation device corresponding to a slot deployment position of a network interface card slot of an in-place network interface card device, a higher operating parameter is allocated to the first heat dissipation device. In some embodiments, in a case where the first heat dissipation device is not a heat dissipation device corresponding to a slot deployment position of a network interface card slot of an in-place network interface card device, an operating parameter is allocated to the first heat dissipation device on the basis of a distance between the first heat dissipation device and the heat dissipation device corresponding to the slot deployment position of the network interface card slot of the in-place network interface card device, wherein the distance is inversely proportional to the operating parameter.

In some embodiments, the target operating parameter may be determined on the basis of the distribution information of the first heat dissipation device by, but not limited so: in response to the distribution information being configured to indicate that the first heat dissipation device is a heat dissipation device in the heat dissipation device array whose device deployment position has a corresponding relationship with a target slot deployment position, acquiring a maximum operating parameter of the first heat dissipation device; and determining the maximum operating parameter as the target operating parameter.

In some embodiments of the present disclosure, in a case where the first heat dissipation device is a heat dissipation device in the heat dissipation device array whose device deployment position has a corresponding relationship with the target slot deployment position, it is possible to, but not limited so, configure the first heat dissipation device to operate on the basis of the maximum operating parameter.

In some embodiments, the target operating parameter may be determined on the basis of the distribution information of the first heat dissipation device by, but not limited so: in response to the distribution information being configured to indicate that a target slot deployment position of the first heat dissipation device comprises a first device deployment position and a second device deployment position, allocating an operating parameter to a heat dissipation device of the first heat dissipation devices on the basis of the maximum operating parameter of the first heat dissipation device and a distance between the heat dissipation devices of the first heat dissipation devices, wherein the first device deployment position is a device deployment position corresponding to the target slot deployment position searched from the slot deployment position and the device deployment position that have a corresponding relationship, and the second device deployment position is a device deployment position whose distance from the first device deployment position falls within a target distance range; and determining the operating parameter having the corresponding relationship with the heat dissipation devices as the target operating parameter.

In some embodiments of the present disclosure, in a case where the target slot deployment position of the first heat dissipation device comprises a first device deployment position and a second device deployment position, it is possible to, but not limited so, allocate the operating parameter to the heat dissipation device of the first heat dissipation devices on the basis of the maximum operating parameter of the first heat dissipation devices and the distance between the heat dissipation devices of the first heat dissipation devices, for example: a first operating parameter is allocated to the heat dissipation device in the first device deployment position and a second operating parameter is allocated to the heat dissipation device in the second device deployment position, wherein the second operating parameter is less than or equal to the first operating parameter. In a case where a plurality of second device deployment positions are included, it is possible to, but not limited so, gradually decrease the second operating parameter as the distance between the second device deployment position and the first device deployment position increases.

In some embodiments, the operating parameter may be allocated to the heat dissipation device of the first heat dissipation devices on the basis of the maximum operating parameter of the first heat dissipation devices and a distance between the heat dissipation devices of the first heat dissipation devices by, but not limited so: determining, on the basis of the maximum operating parameter of the first heat dissipation device, a first operating parameter for the heat dissipation device in the first device deployment position, wherein the first operating parameter is less than or equal to the maximum operating parameter; and determining, on the basis of the first operating parameter and a distance between the second device deployment position and the first device deployment position, a second operating parameter for the heat dissipation device in the second device deployment position, wherein the distance is inversely proportional to the second operating parameter.

In some embodiments of the present disclosure, it is possible to, but not limited so, determine the maximum operating parameter of the first heat dissipation device as the first operating parameter of the heat dissipation device in the first device deployment position. In some embodiments, a value less than the maximum operating parameter of the first heat dissipation device is obtained as the first operating parameter of the heat dissipation device in the first device deployment position.

In some embodiments of the present disclosure, it is possible to, but not limited so, allocate the second operating parameter to the heat dissipation device in the second device deployment position on the basis of the first operating parameter and the distance between the second device deployment position and the first device deployment position, for example, the second operating parameter allocated to the heat dissipation device in the second device deployment position decreases gradually as the distance increases.

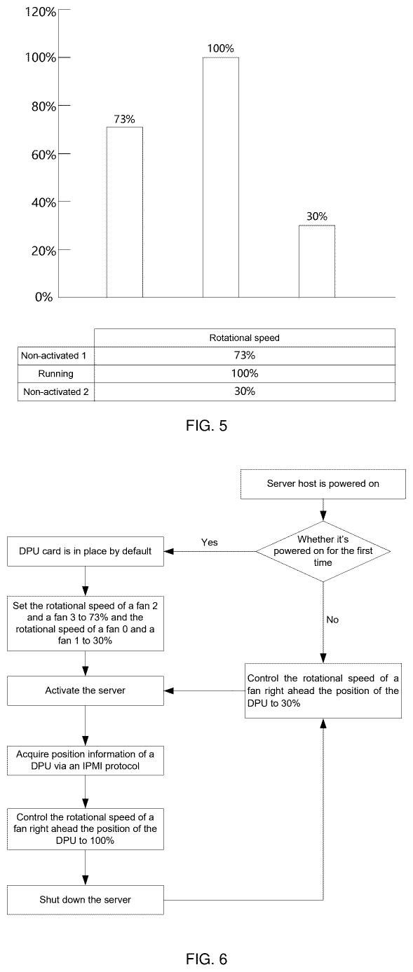

In some embodiments, an example of a rotational speed of a fan is provided. FIG. 5 is a schematic diagram of a rotational speed of a fan according to embodiments of the present disclosure. As shown in FIG. 5, in an example where the heat dissipation device is a fan and the operating parameter of the heat dissipation device is the rotational speed of the fan, the server controller may adjust the rotational speed of the fan to adjust the operating parameter of the heat dissipation device by, but not limited so:
during the operation of the server, maintaining the fan in a device deployment position corresponding to a slot deployment position of a network interface card slot connected to a network interface card device to operate at a rotational speed of 100%, enabling the fan to operate at high power to cool a smart network interface card.

In a case where the server is in a non-activation state, the fan in a device deployment position corresponding to a slot deployment position of a network interface card slot connected to a network interface card device is maintained to operate at a rotational speed of 73%, and the fan in a device deployment position corresponding to a slot deployment position of a network interface card slot not connected to a network interface card device is maintained to operate at a rotational speed of 30%. Such an operation mode can ensure that even if the connection position of the network interface card device changes when the server is activated, the temperature of the server remains within a normal range to prevent the failure of the server due to overheating.

In some embodiments of the present disclosure, to better understand the working process of the server controller hereinabove in the method for controlling a heat dissipation device of a server proposed in the present disclosure, the process hereinabove is further described below in combination with optional embodiments, but is not intended to limit the technical solutions of the embodiments of the present disclosure.

In some embodiments, an example of a working process of a server controller is provided. FIG. 6 is a flowchart of a working process of a server controller according to embodiments of the present disclosure. As shown in FIG. 6, in an example where a network interface card device is a DPU and a heat dissipation device comprises a fan 1, a fan 2, a fan 3 and a fan 4, the server controller may work by, but not limited so:
determining whether the server host is powered on for the first time in a case where the server host is powered on;
in a case where the server host is powered on for the first time, determining a DPU card to be in place by default, setting the rotational speed of the fan 2 and the fan 3 to 73% and the rotational speed of a fan 0 and the fan 1 to 30% and activating the server; in a case where the server is activated, obtaining the position information of the DPU via an IPMI protocol, and controlling the rotational speed of the fan right ahead the position of the DPU to be 100%; and
in a case where the server host is not powered on for the first time, controlling the rotational speed of the fan right ahead the DPU position of the DPU that was in-place before the last powered off to be 30%.

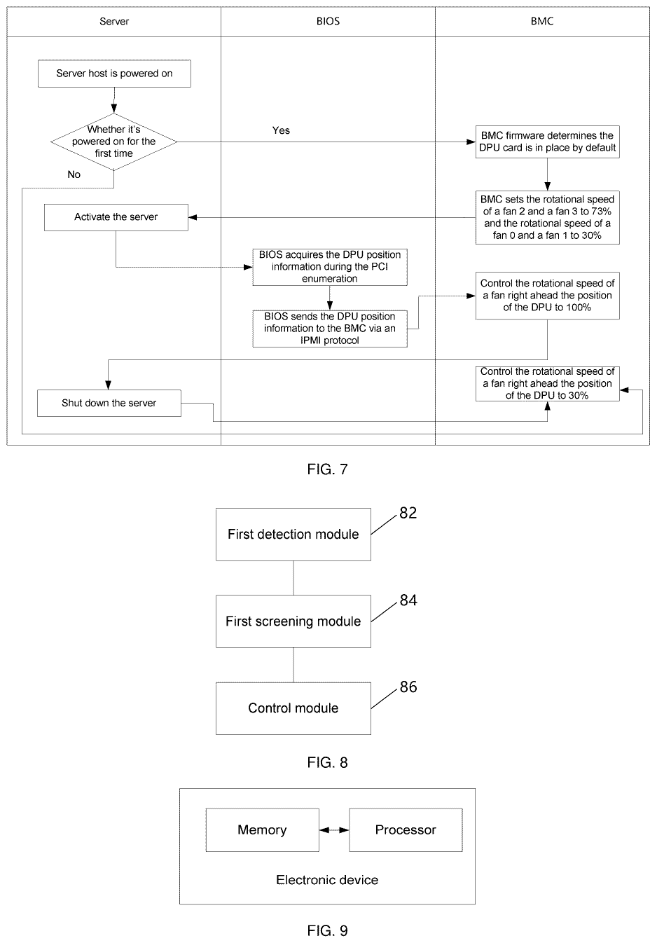

In some embodiments, an example of a control process for a heat dissipation device of a server is provided. FIG. 7 is a swimlane diagram of a control process for a heat dissipation device of a server according to embodiments of the present disclosure. As shown in FIG. 7, in an example where the server controller is a BMC, the basic input/output system is a BIOS, the network interface card device is a DPU, and the heat dissipation device comprises a fan 1, a fan 2, a fan 3 and a fan 4, the heat dissipation device of the server may be controlled to dissipate heat for the server by, but not limited so:
in a case where the server is powered on and no activation operation has been performed within a historical time period, making the BMC impossible to acquire whether the DPU card is in place or an auxiliary firmware CPLD (Complex Programmable Logic Device) also impossible to detect whether the DPU card is in place, resulting in the BMC being incapable of accurately detecting the position information of the DPU card, and thus allowing the BMC to determine that the DPU card is in place by default (condition 1);
in a case where the server is powered on and an activation operation has been performed within the historical time period, acquiring DPU position information obtained during PCI enumeration in the previous activation operation process (condition 2);
under the condition 1, allowing the BMC to control all heat dissipation devices to operate, for example, setting the rotational speeds of the fan 2 and the fan 3 to 73% of the maximum rotational speed, and setting the rotational speeds of the fan 0 and the fan 1 to 30% of the maximum rotational speed; and
under the condition 2, allowing the BMC to control the heat dissipation device corresponding to the acquired DPU position information to operate, for example, setting the rotational speed of the fan corresponding to the DPU position information to 30% of the maximum rotational speed.

In a case where the server is activated, the BIOS determines the position information of the DPU card by identifying a PCI device during the PCI enumeration process of the activation stage.

The BIOS transmits the identified position information of the DPU card to the BMC side via an IPMI protocol or other protocols for interacting with the BMC.

The BMC determines the position information of the DPU card on the basis of the position information transmitted by the BIOS and sets the rotational speed of the fan right ahead the DPU card to the maximum rotational speed, thereby reducing the power consumption and temperature of the entire server.

It is noteworthy that in the solution proposed by the present disclosure, to address the technical problem that the physical link connection design based on a motherboard server hardware cannot support the server controller in reading the temperature register of the network interface card device via the I2C protocol to control the heat dissipation device of the server for reducing the temperature during server operation and shutdown, the present disclosure determines whether the server where the network interface card device is located is activated after power-on. If no activation occurs after power-on, the server controller determines the presence of the network interface card device by default and adaptively controls the heat dissipation device to operate. After the server is activated, the PCI enumeration portion initiated by the basic input/output system enumerates position information of a PCI slot where the network interface card device is located and transmits the position information of the network interface card device to the server controller via a communication protocol with the server controller. The server controller, on the basis of the position information of the network interface card device, controls the heat dissipation device corresponding to the network interface card device to operate, thereby reducing the overall temperature of the server. Moreover, when the server is shut down, the server controller reduces the power of the heat dissipation device corresponding to the network interface card device since the server controller already knows the position information of the network interface card device. Alternatively, when the server has been activated once and is in a shutdown state, the heat dissipation device corresponding to the network interface card device may be activated since the historically deployed position information of the network interface card device is known. In the solution proposed in the present disclosure, the working mode of the corresponding heat dissipation devices may be adjusted for the servers operating at different stages to achieve cooling for the network interface card device and the entire server only by focusing on whether the server is activated for the first time after power-on and on the position where the network interface card device is deployed.

The method for controlling a heat dissipation device of a server proposed in the present disclosure enables interaction between two firmware, i.e., the basic input/output system and the server controller, via a communication protocol by integrating a server hardware design, that is, the position information of the network interface card device identified by the basic input/output system is transmitted to the server controller which in turn controls the corresponding heat dissipation device to operate on the basis of the position information transmitted by the basic input/output system. Moreover, a solution is provided for determining to adjust the working mode of the corresponding heat dissipation device for the servers operating at different stages by determining whether the server is powered on for the first time. In a case where the position information of the network interface card device cannot be accurately determined, the server controller can still adaptively adjust the operation of the heat dissipation device to reduce the overall temperature and power consumption of the server, thereby ensuring the normality of RAS (Reliability, Availability, and Serviceability) of the server.

Moreover, the method for controlling a heat dissipation device of a server proposed in the present disclosure can meet the actual service requirements of a data center and support servers of any architecture, and exhibits strong versatility and high applicability. The operating security of the server is further improved, ensuring that neither the server nor the network interface card device will experience failure due to overheating under any circumstances.

In the present disclosure, the server comprises a server host and a server controller. The server host is deployed with a network interface card slot array and a heat dissipation device array, wherein a slot deployment position of a network interface card slot in the network interface card slot array corresponds to a device deployment position of a heat dissipation device in the heat dissipation device array. The network interface card slot is configured to be connected to a network interface card device, and the heat dissipation device is configured to dissipate heat for the network interface card device connected to the corresponding network interface card slot. Upon detecting that the server host is activated, the server controller detects a target slot deployment position of a target network interface card slot where a target network interface card device connected to the server host is inserted. A first heat dissipation device in a target device deployment position corresponding to the target slot deployment position is screened from the heat dissipation device array, and the first heat dissipation device is controlled to operate on the basis of a target operating parameter, wherein the target operating parameter is configured to enable the target network interface card device to reach a target operating state through dissipating heat, and the target operating state is a state that allows the target network interface card device to continue operating after the server host is activated. The server controller detects a target slot deployment position of a target network interface card slot where a target network interface card device connected to the server host is inserted, and a first heat dissipation device in a target device deployment position corresponding to the target slot deployment position is screened from a heat dissipation device array, such that the first heat dissipation device can be adjusted in real time to operate on the basis of a target operating parameter even in a case where the heat dissipation device in the heat dissipation device array does not have a physical I2C link to monitor the temperature of the network interface card device to adjust the heat dissipation strategy of the entire server. Therefore, it's possible to solve the problem of low control efficiency of the heat dissipation device of the server, achieving the effect of improving the control efficiency of the heat dissipation device of the server.

With the description above of the embodiments, a person skilled in the art can clearly learn that the method in the embodiments above may be implemented by virtue of a software plus a necessary general-purpose hardware platform or by virtue of a hardware, while in many cases, a software plus a necessary general-purpose hardware platform is a preferable implementation. On the basis of such understanding, the technical solution of the present disclosure is essentially embodied in a form of a software product, or a portion the technical solution of the present disclosure contributing to the related art may be embodied in a form of a software product. The computer software product is stored in a non-transitory readable storage medium (such as a ROM/RAM, a magnetic disk, or an optical disk), and comprises a plurality of instructions configured to cause a terminal device (which may be a mobile phone, a computer, a server, a network device, etc.) to perform the method of each embodiment of the present disclosure.

Embodiments of the present disclosure further provide a apparatus for controlling a heat dissipation device of a server. The server comprises a server host and a server controller. The server host is deployed with a network interface card slot array and a heat dissipation device array. A slot deployment position of a network interface card slot in the network interface card slot array has a corresponding relationship with a device deployment position of a heat dissipation device in the heat dissipation device array. The network interface card slot is configured to be connected to a network interface card device. The heat dissipation device is configured to dissipate heat of the network interface card device connected to the corresponding network interface card slot. The apparatus is applied to the server controller The apparatus is configured to implement the embodiments above and optional embodiments, which have been described and will not be repeated. As used hereinafter, the term “module” may be a combination of software and/or hardware that implements a predetermined function. Although the apparatus described in the following embodiment is preferably implemented in software, an implementation in hardware or a combination of software and hardware is possible and conceivable.

FIG. 8 is a structural block diagram of a control apparatus for a heat dissipation device of a server according to embodiments of the present disclosure. As shown in FIG. 8, the apparatus comprises:
a first detection module 82, configured to detect, in response to detecting the activation of the server host, a target slot deployment position of a target network interface card slot where a target network interface card device connected to the server host is inserted;
a first screening module 84, configured to select, from a heat dissipation device array, a first heat dissipation device in a target device deployment position corresponding to the target slot deployment position; and
a control module 86, configured to control the first heat dissipation device to operate on the basis of a target operating parameter, wherein the target operating parameter is configured to enable the target network interface card device to reach a target operating state through dissipating heat, and the target operating state is a state that allows the target network interface card device to continue operating after the server host is activated.

With the apparatus hereinabove, the server controller detects a target slot deployment position of a target network interface card slot where a target network interface card device connected to the server host is inserted, and a first heat dissipation device in a target device deployment position corresponding to the target slot deployment position is screened from a heat dissipation device array, such that the first heat dissipation device can be adjusted in real time to operate on the basis of a target operating parameter even in a case where the heat dissipation device in the heat dissipation device array does not have a physical I2C link to monitor the temperature of the network interface card device to adjust the heat dissipation strategy of the entire server. Therefore, it's possible to solve the problem of low control efficiency of the heat dissipation device of the server, achieving the effect of improving the control efficiency of the heat dissipation device of the server.

In some embodiments, the first detection module comprises:
a receiving unit, configured to receive the target slot deployment position sent by the server host, wherein the target slot deployment position is detected by the server host during a network interface card device enumeration stage in an activation process.

In some embodiments, the receiving unit is further configured to: receive the target slot deployment position sent by a basic input/output system deployed on the server host to the server controller after the operation of the network interface card device enumeration stage is completed.

In some embodiments, the receiving unit is further configured to: detect an activation progress of the basic input/output system deployed on the server host for activating the server host; send, in response to the activation progress indicating that the basic input/output system has completed the operation of the network interface card device enumeration stage, a target request to the basic input/output system, wherein the target request is configured to request acquisition of a slot deployment position of a network interface card slot where a network interface card device connected to the server host is inserted; and receive the target slot deployment position sent, in response to the target request, by the basic input/output system deployed on the server host to the server controller.

In some embodiments, the first screening module comprises:
a first searching unit, configured to search, from a slot deployment position and a device deployment position that have a corresponding relationship, for a device deployment position corresponding to the target slot deployment position as the target device deployment position; and
a first determining unit, configured to determine a heat dissipation device in the heat dissipation device array that is located in the target device deployment position as a first heat dissipation device.

In some embodiments, the first screening module comprises:
a second searching unit, configured to search, from a slot deployment position and a device deployment position that have a corresponding relationship, for a first device deployment position corresponding to the target slot deployment position;
an acquiring unit, configured to acquire a second device deployment position whose distance from the first device deployment position falls within a target distance range;
a second determining unit, configured to determine the first device deployment position and the second device deployment position as the target device deployment position; and
a third determining unit, configured to determine a heat dissipation device in the heat dissipation device array that is located in the target device deployment position as the first heat dissipation device.

In some embodiments, the control module comprises:
a fourth determining unit, configured to determine a target operating parameter on the basis of distribution information of the first heat dissipation device, wherein the distribution information is configured to indicate distribution of the first heat dissipation device on the server host; and
a control unit, configured to control the first heat dissipation device to operate on the basis of the target operating parameter.

In some embodiments, the fourth determining unit is further configured to: in response to the distribution information being configured to indicate that the first heat dissipation device is a heat dissipation device in the heat dissipation device array whose device deployment position has a corresponding relationship with the target slot deployment position, acquire a maximum operating parameter of the first heat dissipation device; and determine the maximum operating parameter as the target operating parameter.

In some embodiments, the fourth determining unit is further configured to: in response to the distribution information being configured to indicate that a target slot deployment position of the first heat dissipation device comprises a first device deployment position and a second device deployment position, allocate an operating parameter to a heat dissipation device of the first heat dissipation devices on the basis of the maximum operating parameter of the first heat dissipation device and a distance between the heat dissipation devices of the first heat dissipation devices, wherein the first device deployment position is a device deployment position corresponding to the target slot deployment position searched from the slot deployment position and the device deployment position that have a corresponding relationship, and the second device deployment position is a device deployment position whose distance from the first device deployment position falls within a target distance range; and determine the operating parameter having the corresponding relationship with the heat dissipation devices as the target operating parameter.

In some embodiments, the fourth determining unit is further configured to: determine, on the basis of the maximum operating parameter of the first heat dissipation device, a first operating parameter for a heat dissipation device in the first device deployment position, wherein the first operating parameter is less than or equal to the maximum operating parameter; and determine, on the basis of the first operating parameter and a distance between the second device deployment position and the first device deployment position, a second operating parameter for a heat dissipation device in the second device deployment position, wherein the distance is inversely proportional to the second operating parameter.

In some embodiments, the apparatus further comprises:
a second detection module, configured to detect current power-on information of the server host in response to detecting that the server host is powered on, wherein the current power-on information is configured to indicate a power-on condition under which the server host is powered on this time;
a determining module, configured to determine, on the basis of the current power-on information, in-place information of network interface card slots in the network interface card slot array, wherein the in-place information is configured to indicate an in-place condition of a network interface card device on the corresponding network interface card slot; and
a second screening module, configured to screen out, on the basis of the in-place information, a second heat dissipation device from the heat dissipation device array and control the second heat dissipation device to operate on the basis of a reference operating parameter, wherein the reference operating parameter is configured to enable the network interface card slot array to reach a reference operating state through dissipating heat, and the reference operating state is an operating state of the network interface card slot array under which the server host is allowed to be activated.

In some embodiments, the determining module comprises: a fifth determining unit, configured to, in response to the current power-on information being configured to indicate that the server host is powered on for the first time, determine that the in-place information is configured to indicate that there is a network interface card slot in the network interface card slot array that is connected to a network interface card device. The second screening module is further configured to: determine all heat dissipation devices in the heat dissipation device array as the second heat dissipation devices; allocate, on the basis of the device deployment positions of the heat dissipation devices in the heat dissipation device array, operating parameters to the second heat dissipation devices to obtain the reference operating parameter; and control the second heat dissipation devices to operate on the basis of the reference operating parameter.

In some embodiments, the determining module comprises: a sixth determining unit, configured to, in response to the current power-on information being configured to indicate that the server host is not powered on for the first time, determine that the in-place information is configured to indicate that the network interface card device connected to the server host at the time of the server host's last powered off is in place. The second screening module is further configured to: acquire a candidate slot deployment position of the network interface card slot where the network interface card device connected to the server host is located at the time of the server host's last powered off; search, from the slot deployment position and the device deployment position that have a corresponding relationship, for a candidate device deployment position corresponding to the candidate slot deployment position; and determine a heat dissipation device in the candidate device deployment position as the second heat dissipation device.

It should be noted that each of the modules above may be implemented by software or hardware. In the case of hardware, the modules can be implemented by, but is not limited thereby: all the modules above are in the same processor; or the modules above are separately located in different processors in any combination.

Embodiments of the present disclosure further provide a non-transitory computer readable storage medium, storing a computer program therein, wherein the computer program is configured to, when executed, perform the steps in any one of the method embodiments above.

In some embodiments, the non-transitory computer readable storage medium above may include, but is not limited to, various non-transitory readable media capable of storing computer programs, such as a USB flash disk, a read-only memory (ROM), a random access memory (RAM), a mobile hard disk, a magnetic disk, and an optical disk, etc.

Embodiments of the present disclosure further provide an electronic device. FIG. 9 is a structural block diagram of an electronic device according to embodiments of the present disclosure. As shown in FIG. 9, the electronic device above comprises a memory and a processor, wherein the memory stores a computer program therein, and the processor is configured to execute the computer program to perform the steps in any one of the method embodiments above.

In some embodiments, the electronic device above may further comprise a transmission device and an input/output device, wherein the transmission device is connected to the processor above, and the input/output device is connected to the processor above.

Embodiments of the present disclosure further provide a computer program product comprising a computer program, wherein the computer program, when executed by a processor, implements the steps in any one of the method embodiments above.

For specific examples in the embodiments of the present disclosure, reference may be made to the examples described in the embodiments and exemplary embodiments hereinabove, which will not be repeated herein in the embodiments of the present disclosure.

Apparently, a person skilled in the art should understand that the modules or steps above of the present disclosure may be implemented with a general-purpose computing apparatus. The modules or steps can be centralized on a single computing apparatus or distributed on a network formed by a plurality of computing apparatuses, can be implemented with program codes executable by the computing apparatus, and thus can be stored in a storage apparatus and executed by the computing apparatus. Moreover, in some cases, the steps shown or described may be performed in an order different from the order herein or be separately produced as individual integrated circuit modules, or a plurality of the modules or steps may be produced and implemented as a single integrated circuit module. As such, the present disclosure is not limited to any particular combination of hardware and software.

The embodiments described above are merely preferred embodiments of the present disclosure and are not intended to limit the present disclosure. Various modifications and variations can be made to the present disclosure by a person skilled in the art. Any modification, equivalent replacement, improvement and the like made within the principle of the present disclosure shall be encompassed in the scope of protection of the present disclosure.

1. A method for controlling a heat dissipation device of a server, wherein the server comprises a server host and a server controller, wherein the server host is deployed with a network interface card slot array and a heat dissipation device array; a slot deployment position of a network interface card slot in the network interface card slot array has a corresponding relationship with a device deployment position of a heat dissipation device in the heat dissipation device array; the network interface card slot is configured to be connected to a network interface card device; the heat dissipation device is configured to dissipate heat of a network interface card device connected to the corresponding network interface card slot; and the method is applied to the server controller and comprises:
detecting, in response to detecting the activation of the server host, a target slot deployment position of a target network interface card slot where a target network interface card device connected to the server host is inserted;
selecting, from the heat dissipation device array, a first heat dissipation device in a target device deployment position corresponding to the target slot deployment position; and
controlling the first heat dissipation device to operate on the basis of a target operating parameter, wherein the target operating parameter is configured to enable the target network interface card device to reach a target operating state through dissipating heat, and the target operating state is a state that allows the target network interface card device to continue operating after the server host is activated;
wherein selecting, from the heat dissipation device array, the first heat dissipation device in the target device deployment position corresponding to the target slot deployment position comprises: searching, from a slot deployment position and a device deployment position that have a corresponding relationship, for a first device deployment position corresponding to the target slot deployment position; acquiring a second device deployment position whose distance from the first device deployment position falls within a target distance range; determining the first device deployment position and the second device deployment position as the target device deployment position; and determining a heat dissipation device in the heat dissipation device array that is located in the target device deployment position as the first heat dissipation device;
wherein controlling the first heat dissipation device to operate on the basis of the target operating parameter comprises: determining the target operating parameter on the basis of a distribution information of the first heat dissipation device, wherein the distribution information is configured to indicate distribution of the first heat dissipation device on the server host; and controlling the first heat dissipation device to operate on the basis of the target operating parameter.

2. The method as claimed in claim 1, wherein detecting the target slot deployment position of the target network interface card slot where the target network interface card device connected to the server host is inserted, comprises:
receiving the target slot deployment position sent by the server host, wherein the target slot deployment position is detected by the server host during a network interface card device enumeration stage in an activation process.

3. The method as claimed in claim 2, wherein receiving the target slot deployment position sent by the server host comprises:
receiving the target slot deployment position sent by a basic input/output system deployed on the server host to the server controller after the operation of the network interface card device enumeration stage is completed.

4. The method as claimed in claim 2, wherein receiving the target slot deployment position sent by the server host comprises:
detecting an activation progress of a basic input/output system deployed on the server host for activating the server host;
sending, in response to the activation progress indicating that the basic input/output system has completed the operation of the network interface card device enumeration stage, a target request to the basic input/output system, wherein the target request is configured to request acquisition of a slot deployment position of a network interface card slot where a network interface card device connected to the server host is inserted; and
receiving the target slot deployment position sent, in response to the target request, by the basic input/output system deployed on the server host to the server controller.

5. (canceled)

6. (canceled)

7. (canceled)

8. The method as claimed in claim 1, wherein determining the target operating parameter on the basis of the distribution information of the first heat dissipation device comprises:
in response to the distribution information being configured to indicate that the first heat dissipation device is a heat dissipation device in the heat dissipation device array whose device deployment position has a corresponding relationship with the target slot deployment position, acquiring a maximum operating parameter of the first heat dissipation device; and
determining the maximum operating parameter as the target operating parameter.

9. The method as claimed in claim 1, wherein determining the target operating parameter on the basis of the distribution information of the first heat dissipation device comprises:
in response to the distribution information being configured to indicate that the target slot deployment position of the first heat dissipation device comprises a first device deployment position and a second device deployment position, allocating an operating parameter to a heat dissipation device of the first heat dissipation devices on the basis of the maximum operating parameter of the first heat dissipation devices and a distance between the heat dissipation devices of the first heat dissipation devices, wherein the first device deployment position is a device deployment position corresponding to the target slot deployment position searched from a slot deployment position and a device deployment position that have a corresponding relationship, and the second device deployment position is a device deployment position whose distance from the first device deployment position falls within a target distance range; and
determining the operating parameter having the corresponding relationship with the heat dissipation devices as the target operating parameter.

10. The method as claimed in claim 9, wherein allocating the operating parameter to the heat dissipation device of the first heat dissipation devices on the basis of the maximum operating parameter of the first heat dissipation devices and the distance between the heat dissipation devices of the first heat dissipation devices comprises:
determining, on the basis of the maximum operating parameter of the first heat dissipation device, a first operating parameter for a heat dissipation device in the first device deployment position, wherein the first operating parameter is less than or equal to the maximum operating parameter; and
determining, on the basis of the first operating parameter and a distance between the second device deployment position and the first device deployment position, a second operating parameter for a heat dissipation device in the second device deployment position, wherein the distance is inversely proportional to the second operating parameter.

11. The method as claimed in claim 9, wherein allocating the operating parameter to the heat dissipation device of the first heat dissipation devices on the basis of the maximum operating parameter of the first heat dissipation devices and the distance between the heat dissipation devices of the first heat dissipation devices comprises:
allocating a first operating parameter to a heat dissipation device in the first device deployment position and allocating a second operating parameter to a heat dissipation device in the second device deployment position, wherein the first operating parameter is less than or equal to the maximum operating parameter, and the second operating parameter is less than or equal to the first operating parameter.

12. The method as claimed in claim 1, wherein before detecting the target slot deployment position of the target network interface card slot where the target network interface card device connected to the server host is inserted, the method further comprises:
in response to detecting that the server host is powered on, detecting current power-on information of the server host, wherein the current power-on information is configured to indicate a power-on condition under which the server host is powered on this time;
determining, on the basis of the current power-on information, in-place information of a network interface card slot in the network interface card slot array, wherein the in-place information is configured to indicate an in-place condition of a network interface card device on the corresponding network interface card slot; and
screening out, on the basis of the in-place information, a second heat dissipation device from the heat dissipation device array and controlling the second heat dissipation device to operate on the basis of a reference operating parameter, wherein the reference operating parameter is configured to enable the network interface card slot array to reach a reference operating state through dissipating heat, and the reference operating state is an operating state of the network interface card slot array under which the server host is allowed to be activated.

13. The method as claimed in claim 12, wherein determining, on the basis of the current power-on information, in-place information of the network interface card slot in the network interface card slot array comprises: in response to the current power-on information being configured to indicate that the server host is powered on for the first time, determining that the in-place information is configured to indicate that there is a network interface card slot in the network interface card slot array that is connected to a network interface card device; and
screening out, on the basis of the in-place information, the second heat dissipation device from the heat dissipation device array and controlling the second heat dissipation device to operate on the basis of the reference operating parameter comprises: determining all heat dissipation devices in the heat dissipation device array as the second heat dissipation devices; allocating, on the basis of the device deployment positions of the heat dissipation devices in the heat dissipation device array, operating parameters to the second heat dissipation devices to obtain the reference operating parameter; and controlling the second heat dissipation devices to operate on the basis of the reference operating parameter.

14. The method as claimed in claim 12, wherein
determining, on the basis of the current power-on information, in-place information of the network interface card slot in the network interface card slot array comprises: in response to the current power-on information being configured to indicate that the server host has never been activated, determining that the in-place information is configured to indicate that a default network interface card slot in the network interface card slot array is connected to a network interface card device; and
screening out, on the basis of the in-place information, the second heat dissipation device from the heat dissipation device array comprises: determining, as the second heat dissipation device, a heat dissipation device in the heat dissipation device array whose device deployment position corresponds to a slot deployment position of the default network interface card slot.

15. The method as claimed in claim 12, wherein
determining, on the basis of the current power-on information, in-place information of the network interface card slot in the network interface card slot array comprises: in response to the current power-on information being configured to indicate that the server host has been activated before, determining the in-place information of the network interface card slot in the network interface card slot array on the basis of a target slot deployment position of a target network interface card slot of a target network interface card device connected to the server host, as detected during historical activation of the server host; and
screening out, on the basis of the in-place information, the second heat dissipation device from the heat dissipation device array comprises: determining, as the second heat dissipation device, a heat dissipation device in the heat dissipation device array that corresponds to the slot deployment position of the network interface card slot of the network interface card device connected to the server host, as detected during historical activation of the server host.

16. The method as claimed in claim 12, wherein
determining, on the basis of the current power-on information, in-place information of the network interface card slot in the network interface card slot array comprises: in response to the current power-on information being configured to indicate that the server host is not powered on for the first time, determining that the in-place information is configured to indicate that the network interface card device connected to the server host at the time of the server host's last powered off is in place; and
screening out, on the basis of the in-place information, the second heat dissipation device from the heat dissipation device array comprises: acquiring a candidate slot deployment position of the network interface card slot where the network interface card device connected to the server host is located at the time of the server host's last powered off; searching, from a slot deployment position and a device deployment position that have a corresponding relationship, for a candidate device deployment position corresponding to the candidate slot deployment position; and determining a heat dissipation device in the candidate device deployment position as the second heat dissipation device.

17. (canceled)

18. A non-transitory computer readable storage medium, wherein the non-transitory computer readable storage medium stores a computer program therein, wherein the computer program, when executed by a processor, implements the following steps, comprises:
detecting, in response to detecting the activation of a server host, a target slot deployment position of a target network interface card slot where a target network interface card device connected to the server host is inserted; wherein the server comprises a server host and a server controller, wherein the server host is deployed with a network interface card slot array and a heat dissipation device array; a slot deployment position of a network interface card slot in the network interface card slot array has a corresponding relationship with a device deployment position of a heat dissipation device in the heat dissipation device array; the network interface card slot is configured to be connected to a network interface card device; the heat dissipation device is configured to dissipate heat of a network interface card device connected to the corresponding network interface card slot;
selecting, from the heat dissipation device array, a first heat dissipation device in a target device deployment position corresponding to the target slot deployment position; and
controlling the first heat dissipation device to operate on the basis of a target operating parameter, wherein the target operating parameter is configured to enable the target network interface card device to reach a target operating state through dissipating heat, and the target operating state is a state that allows the target network interface card device to continue operating after the server host is activated;
wherein selecting, from the heat dissipation device array, the first heat dissipation device in the target device deployment position corresponding to the target slot deployment position comprises: searching, from a slot deployment position and a device deployment position that have a corresponding relationship, for a first device deployment position corresponding to the target slot deployment position; acquiring a second device deployment position whose distance from the first device deployment position falls within a target distance range; determining the first device deployment position and the second device deployment position as the target device deployment position; and determining a heat dissipation device in the heat dissipation device array that is located in the target device deployment position as the first heat dissipation device;
wherein controlling the first heat dissipation device to operate on the basis of the target operating parameter comprises: determining the target operating parameter on the basis of a distribution information of the first heat dissipation device, wherein the distribution information is configured to indicate distribution of the first heat dissipation device on the server host; and controlling the first heat dissipation device to operate on the basis of the target operating parameter.

19. An electronic device, comprising a memory, a processor, and a computer program stored on the memory and executable on the processor, wherein the processor, when executing the computer program, causes the processor to: detect, in response to detecting the activation of a server host, a target slot deployment position of a target network interface card slot where a target network interface card device connected to the server host is inserted; wherein the server comprises a server host and a server controller, wherein the server host is deployed with a network interface card slot array and a heat dissipation device array; a slot deployment position of a network interface card slot in the network interface card slot array has a corresponding relationship with a device deployment position of a heat dissipation device in the heat dissipation device array; the network interface card slot is configured to be connected to a network interface card device; the heat dissipation device is configured to dissipate heat of a network interface card device connected to the corresponding network interface card slot;
select, from the heat dissipation device array, a first heat dissipation device in a target device deployment position corresponding to the target slot deployment position; and
control the first heat dissipation device to operate on the basis of a target operating parameter, wherein the target operating parameter is configured to enable the target network interface card device to reach a target operating state through dissipating heat, and the target operating state is a state that allows the target network interface card device to continue operating after the server host is activated;
wherein selecting, from the heat dissipation device array, the first heat dissipation device in the target device deployment position corresponding to the target slot deployment position comprises: searching, from a slot deployment position and a device deployment position that have a corresponding relationship, for a first device deployment position corresponding to the target slot deployment position; acquiring a second device deployment position whose distance from the first device deployment position falls within a target distance range; determining the first device deployment position and the second device deployment position as the target device deployment position; and determining a heat dissipation device in the heat dissipation device array that is located in the target device deployment position as the first heat dissipation device;
wherein controlling the first heat dissipation device to operate on the basis of the target operating parameter comprises: determining the target operating parameter on the basis of a distribution information of the first heat dissipation device, wherein the distribution information is configured to indicate distribution of the first heat dissipation device on the server host; and controlling the first heat dissipation device to operate on the basis of the target operating parameter.

20. (canceled)

21. The method as claimed in claim 12, wherein the reference operating parameter is determined according to a temperature condition for the normal activation of the server host and the heat generated during the activation process of the server host, and the reference operating parameter comprises at least one of the following: rotational speed and air volume of a heat dissipation device.

22. The method as claimed in claim 1, wherein the target distance range is determined by at least one of the following:
in a case where the network interface card slot array is in a parallel arrangement, determining a certain horizontal distance as the target distance range hereinabove;
in a case where the network interface card slot array is in a vertical arrangement, determining a certain vertical distance as the target distance range hereinabove;
in a case where the network interface card slot array is in a hybrid arrangement comprising both parallel arrangement and vertical arrangement, determining a distance within a certain radius as the target distance range.

23. The method as claimed in claim 1, wherein the corresponding relationship between the slot deployment position of the network interface card slot in the network interface card slot array and the device deployment position of the heat dissipation device in the heat dissipation device array comprises: a one-to-one corresponding relationship, or a many-to-many corresponding relationship; and the first heat dissipation devices are the same number of heat dissipation devices as the target slot deployment positions, or a different number of heat dissipation devices.

24. The method as claimed in claim 2, wherein the network interface card device enumeration stage is configured to allocate a bus number and allocate a BAR (Base Address Register) space, wherein the allocated bus number is configured to access a configuration space, and the BAR space is configured to perform data interaction with a PCIe (Peripheral Component Interconnect express) device.

25. The method as claimed in claim 1, wherein selecting, from the heat dissipation device array, the first heat dissipation device in the target device deployment position corresponding to the target slot deployment position comprises:
searching, from a slot deployment position and a device deployment position that have a corresponding relationship, for a device deployment position corresponding to the target slot deployment position as the target device deployment position; and
determining a heat dissipation device in the heat dissipation device array that is located in the target device deployment position as the first heat dissipation device.
